(19) United States
(12) Patent Application Publication
(10) Pub. No.: US 2004/0108505 A1
(43) Pub. Date: Jun. 10, 2004

(54) Method for p-type doping wide band gap oxide semiconductors

(76) Inventors: Harry L. Tuller, Wellesley, MA (US); Theodore Moustakas, Dover, MA (US); Yong Ki Min, Chandler, AZ (US)

Correspondence Address: Matthew E. Connors, Gauthier & Connors LLP, Suite 3300, 225 Franklin Street, Boston, MA, 02110, US

(21) Appl. No.: 10/663,531

(22) Filed: Sep. 16, 2003

Related U.S. Application Data
(60) Provisional application No. 60/411,086, filed on Sep. 16, 2002.
(60) Provisional application No. 60/411,249, filed on Sep. 17, 2002.

(51) Int. Cl. H01L 31/0256

(52) U.S. Cl. 257/76

(57) ABSTRACT

A method of p-type doping in ZnO is provided. The method includes forming an acceptor-doped material having ZnO under reducing conditions, thereby insuring a high donor density. Also, the specimens of the acceptor-doped material are annealed at intermediate temperatures under oxidizing conditions so as to remove intrinsic donors and activate impurity acceptors.

### PRIORITY INFORMATION

This application claims priority from provisional application Ser. No. 60/411,086 filed on Sep. 16, 2002 and provisional application Ser. No. 60/411,249 filed on Sep. 17, 2002, both of which are incorporated herein by reference in their entireties.

### BACKGROUND OF THE INVENTION

The invention relates to p-type doping in ZnO, and in particular to p-type doping in a wide band gap oxide semiconductor.

Interest in wide band gap semiconductors has grown rapidly in recent years following the successful growth of high quality nitrides and their implementation in blue, green and UV LEDS, lasers and detectors. Similar progress in the use of wide band gap oxides in electronic or photonic devices has been greatly hampered by the inability to fabricate both n- and p-type versions of common semiconducting oxides. The availability of oxide p-n junctions would open many new scientific and technological opportunities tied to the potential for the integration of semiconducting with the ferroelectric, piezoelectric, electro-optic, luminescent, chemical sensing and other functions characteristic of various oxide systems.

It has been shown possible to grow low resistivity p-type ZnO by utilizing N and Ga as reactive co-dopants. The films were produced by pulsed laser deposition combined with a plasma gas source. Active nitrogen was produced by passing N₂O through an ECR source and Ga co-doping was obtained by doping the ZnO targets with various percentages of Ga₂O₃. It was understood that plasma-activated N₂O is effective in preventing the formation of O-vacancies while simultaneously introducing N as an acceptor. Films produced without Ga co-doping were found to be p-type but with very low carrier concentration (10¹⁰ cm⁻³). Even with Ga co-doping, the results were found to depend critically on the percentage of Ga in the ZnO target. Furthermore, the mobility of the p-type films were very low (<1 cm²/NV-s), suggesting that the films were, nevertheless, highly compensated.

In addition, p-type ZnO was produced at room temperature by chemical vapor deposition, via N doping using NH₃. However, that work showed poor reproducibility, high resistance (typically 100 Ω-cm) and low carrier concentrations (˜1×10¹⁶ cm⁻³).

P-type doped ZnO films have also been synthesized on GaAs substrates with arsenic (As) as the dopant by an interdiffusion process. During pulsed laser heating of the ZnO film, arsenic atoms from the GaAs substrate diffused into the newly formed ZnO layer. However, non-uniform arsenic concentrations across the ZnO thickness and high concentration of gallium (Ga) in vicinity of the interface between the ZnO films and GaAs substrate were observed.

The method of co-doping has also been employed for p-type doping of the family of III-Nitrides. When grown by the MOCVD method, the incorporation of Mg acceptors is facilitated by the simultaneous incorporation of H. It has been shown that post growth treatments, such as annealing or Low Energy Electron Bombardment Irradiation (LEEBI), removes the H and leaves the Mg as the sole dopant (acceptor) in the lattice. During growth by plasma-assisted MBE, it has been proposed that the incorporation of Mg is facilitated by the electrons at the surface of the growing film arriving from the plasma source. In this method the co-dopants are the electrons, which drain to ground during film growth and thus no post-growth anneals are required to activate the Mg. Thus, in this class of semiconductors, the co-dopants (hydrogen or electrons) increase the solubility of the Mg acceptors and are removed either during or after film growth. This is to be contrasted with the way co-doping is currently practiced in ZnO where the co-dopants remain in the lattice after growth and act as compensating defects.

It is a well known fact that oxygen-deficient ZnO is highly conductive and n-type. However, the oxygen deficiency is a strong function of annealing conditions. For example, ZnO films with resistivity of 4.5×10⁻⁴ ohm-cm, prepared by rf-magnetron sputtering, have been found to be unstable above 150° C. On the other hand, films prepared with Al doping have been found to achieve similar low levels of resistivity but remain stable to 400° C. Films with resistivities as low as ˜1−8×10⁻⁴ ohm-cm and carrier densities as high as 3−15×10²⁰ cm⁻³ are now routinely obtained by substitution of Group III (Al, Ga, In), or Group IV (Si, Ge) elements onto Zn sites or F onto O sites.

Bulk ZnO (single and polycrystalline) is always observed to exhibit metal excess (or equivalently oxygen deficiency) under experimentally attainable oxygen partial pressures. The metal excess, incorporated either as zinc interstitials (Znᵢ) or oxygen vacancies (Vo), as illustrated in FIG. 1, normally give rise to substantial n-type conductivity in spite of its large band gap (˜3.34 eV at room temperature). This is attributable to the shallow donor levels (0.05 eV) thereby formed, and, for oxides, the very high electron mobility of 150-200 cm²V-s. Although metal deficient ZnO and accompanying p-type conductivity have not been obtained experimentally in undoped ZnO, nearly compensated, electrically insulating materials have been shown to be obtainable by substitutional incorporation of monovalent dopants such as Li. While some controversy remains, Frenkel equilibria on the Zn lattice is believed to be the dominant form of intrinsic ionic disorder at intermediate temperatures with Schottky disorder becoming increasingly important at higher temperatures. This is consistent with observations that zinc diffusion is significantly greater than that of oxygen to temperatures of ˜1300° C.

The following equation lists the simplified electroneutrality relation which ignores minority oxygen vacancies but includes contributions from a donor impurity D_{Zn}.

n=[V′_{zn}]+2[V″_{Zn}]=p+[Znᵢ^{•}]+2[Znᵢ^{••}]+[D_{Zn}^{•]} (1)

FIGS. 2A and 2B show defect diagrams for undoped and donor doped (deep donor with 2 eV ionization energy) ZnO at 600° C. based on calculations using the above defect model. The roman numerals at the top of the figure refer to regions for which different pairs of defects listed in Eq. 1 dominate the electroneutrality relation. For example, in FIG. 2B, electrons are predominantly derived from shallow intrinsic Znᵢ donors in region II, while in III, they are derived from the deep donor D_{Zn}. Such models are employed in accordance with the invention to select growth and anneal conditions that are optimized to achieve high quality p-type ZnO.

The incorporation of impurities can also be described by defect chemical reactions. For example, trivalent atoms, typified by aluminum, gallium and indium, are incorporated as donors as described as

$${Al}_{2} {O}_{3} = 2 {Al}_{Zn}^{•} + 2 {e}^{′} + 2 {O}_{o} + \frac{1}{2} {O}_{2} \qquad ( 2 )$$

where Al substituting on a Zn site with a net positive charge is compensated by an electron. Similarly, lithium incorporation can be written as

$${Li}_{2} O + \frac{1}{2} {O}_{2} = 2 {Li}_{Zn}^{′} + 2 {h}^{•} + 2 {O}_{o} \qquad ( 3 )$$

where Li substitutes on a Zn site with a net negative charge and is compensated by a hole. Unfortunately, it is known, however, that Li also readily enters the ZnO lattice interstitially resulting in a donor center. This results in n-type conduction or acceptor-donor compensation ([Li′_{zn}]=[Liᵢ^{•}]).

### SUMMARY OF THE INVENTION

According to one aspect of the invention, there is provided a method of p-type doping in ZnO. The method includes forming an acceptor-doped material having ZnO under reducing conditions, thereby insuring a high donor density. Also, the specimens of the acceptor-doped material are annealed at intermediate temperatures under oxidizing conditions so as to remove intrinsic donors and activate impurity acceptors.

According to another aspect of the invention, there is provided a method of forming p-n junctions using p-type ZnO. The method includes forming an acceptor-doped material having ZnO under reducing conditions, thereby insuring a high donor density. Also, the specimens of the acceptor-doped material are annealed at intermediate temperatures under oxidizing conditions so as to remove intrinsic donors and activate impurity acceptors.

According to another aspect of the invention, there is provided a wide band gap semiconductor device. The wide band gap semiconductor device includes an acceptor-doped material having ZnO that is formed under reducing conditions, thereby insuring a high donor density. The specimens of the acceptor-doped material are annealed at intermediate temperatures under oxidizing conditions so as to remove intrinsic donors and activate impurity acceptors.

According to another aspect of the invention, there is provided a p-n junction. The p-n junction includes an acceptor-doped material having ZnO that is formed under reducing conditions, thereby insuring a high donor density. The specimens of the acceptor-doped material are annealed at intermediate temperatures under oxidizing conditions so as to remove intrinsic donors and activate impurity acceptors.

### BRIEF DESCRIPTION OF THE DRAWINGS

FIG. 1 is a schematic diagram demonstrating point defects in crystalline solids;

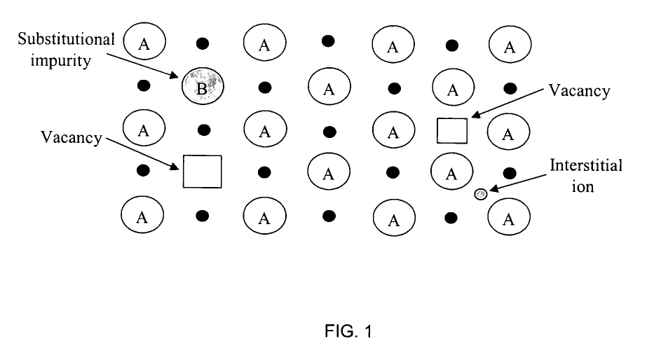

FIG. 2A is a graph demonstrating defect concentrations as a function of log PO₂ for nominally undoped ZnO at 600° C.; FIG. 2B is graph demonstrating defect concentrations as a function of log PO₂ for nominally donor doped ZnO at 600° C.;

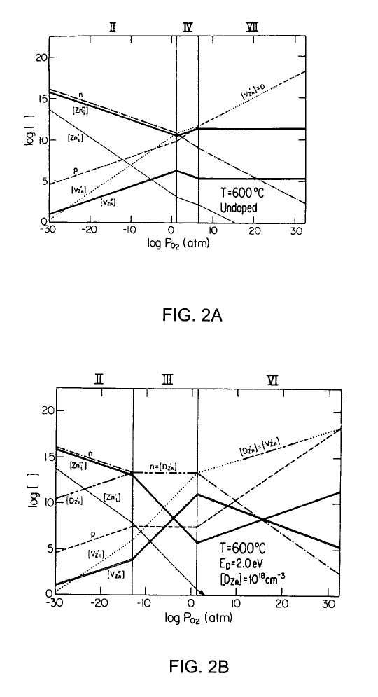

FIG. 3 is a flowchart describing the steps needed to accomplish the invention;

FIGS. 4A-4D are schematic block diagrams demonstrating the formation of a p-n junction; and

FIG. 5 is a schematic diagram of the crystal structure of ZnO.

### DETAILED DESCRIPTION OF THE INVENTION

The realization of oxide p-n homo-junctions opens many new scientific and technological opportunities tied to their ease of processing and high temperature stability in ambient environments, and the potential for integration of semiconducting with the ferroelectric, piezoelectric, electro-optic, luminescent, gas sensing and ferromagnetic functions characteristic of various oxide systems. What remains lacking is both a reliable and reproducible means for fabricating high quality p-type ZnO and corresponding p-n junctions and an underlying understanding of the thermodynamic and kinetic processes which control dopant incorporation, defect generation and transport and stability to elevated temperatures. The invention provides a method to achieve p-type doping in ZnO by a modified co-doping method, which is here termed the transient co-doping (TCD) method. This method, is understood to form highly p-type films with minimal compensation and high hole mobility.

While acceptors such as Li and N are known to go into solid solution in ZnO, they normally fail to drive the material p-type with high levels of conductivity. In the case of Li, this is known to be due to self compensation by the formation of donor-like Li interstitials. In the case of dopants such as N, it is believed that this is due to self-compensation by native donors such as Zn interstitials or O vacancies that readily form in this compound. Indeed much of the limited success to date in obtaining p-type ZnO was achieved by intentional self-compensation with impurity donors, e.g. Ga+N. This, however, tends to lead to partial compensation as indicated by the very low carrier mobilities (less than one).

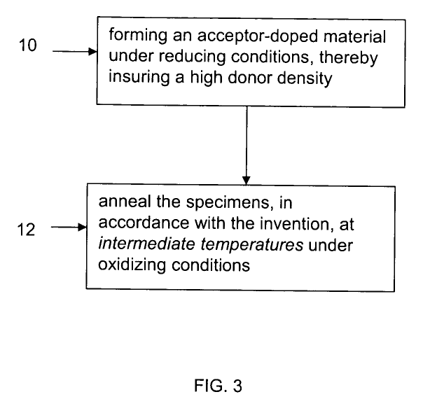

FIG. 3 is a flowchart describing the steps needed to accomplish the TCD method. The first step 10 of the TCD method is forming an acceptor-doped material under reducing conditions, thereby insuring a high donor density. In a hydrogen containing atmosphere, this would be due to hydrogen interstitials while for a non- hydrogen containing atmosphere, it will be due to intrinsic lattice defects such as Zn interstitials. The solid is able to reduce its overall energy in the presence of the acceptor states given the ability of the donor electrons to drop down in energy into the acceptor states. This process becomes more probable with increasing band gap since this decreases the overall energy required to incorporate the defects even further. Thus a high donor concentration will, in turn, accommodate a high impurity acceptor density into solid solution.

Following growth, the second step 12 of the TCD method is to anneal the specimens, in accordance with the invention, at intermediate temperatures under oxidizing conditions between approximately 200° C. and 700° C. This step serves to remove the hydrogen interstitials or intrinsic donors (transient co-dopant) and thereby activate the impurity acceptors. Given the appropriate annealing conditions, it is understood that the acceptors remain in solution due to kinetic considerations.

Although ZnO can be made n-type by stoichiometry deviations, it is preferred in preparing permanently n-type ZnO that such be achieved by impurity doping. For example, ZnO films can be doped n-type with Ga or Al. These elements are ideal as substitutional donors because of the similarity of the radii of these atoms in tetrahedral coordination (1.26 Å) to that of Zn (1.31 Å). To verify that doping is the result of the incorporation of impurities rather than incorporation of native defects, the activation energy of free carrier concentration versus the inverse of the temperature of the Ga or Al effusion cells can be compared with the activation energy of the vapor pressure of these elements in the same temperature range.

ZnO films of both polarities can be doped p-type by incorporation of nitrogen during film growth. Nitrogen is an ideal p-type dopant on the oxygen site given the similar atomic radii in tetrahedral coordination of the two elements (N=0.70 Å and O=0.66 Å). Both molecular nitrogen as well N₂O, activated by the RF plasma source, can be employed. The partial pressures of these gases, as well as the partial pressure of hydrogen or oxygen can be varied in order to increase the solubility of nitrogen in the films by simultaneous co-doping. It is understood in accordance with the invention that the as-grown films are semi-insulating due to compensation. The p- type dopants are activated by annealing the films in controlled oxygen partial pressure at a range of temperatures beginning at about 200° C. for the hydrogen co-doped ZnO, and about 500° C. for the non-hydrogen reduced ZnO.

Due to large lattice and thermal stresses, direct growth on (0001) sapphire has been shown to lead to ZnO films with rough surface morphology and poor crystalline quality. In accordance with the invention, growth on various types of buffers can be carried out, following conventional approaches.

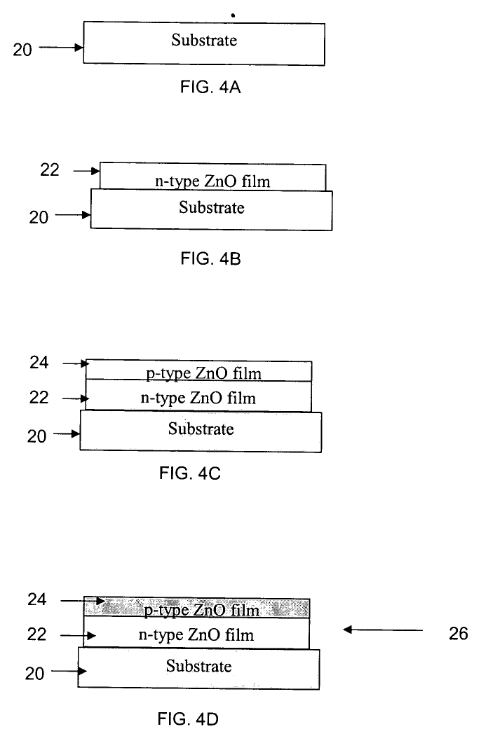

ZnO p-n junctions are formed, in accordance with the invention, by first preparing a substrate 20, as shown in FIG. 4A. A layer 22 of n-ZnO doped with Ga or Al is grown on the substrate 20 having a thickness of 1000 nm, as shown in FIG. 4B. A p-type ZnO film 24 is deposited on the top of the n-type ZnO film 22, which is introduced during the reduction treatment, as shown in FIG. 4C. The film 24 at this stage is poorly conductive, given compensation of N acceptor with volatile donors, such as oxygen vacancies. In addition, the thin film 24 has a thickness of 500 nm. The structure 26 is annealed in air to activate p-type conductivity, as shown in FIG. 4D. Note that this method produces p-n junctions that are superior to previously reported p-n junctions.

While there have been measured results for Zn and O diffusion in ZnO much of such prior techniques were performed under conditions for which ZnO has a high vapor pressure. Thus, experimentally measured defect profiles reflected not only in-diffusion but also a moving surface boundary whose rate is dependent on evaporative loss. There has been completed a series of cation and oxygen diffusion measurements extending up to 1300° C. in which the diffusion specimens were isolated in a ZnO cavity during anneal to minimize evaporative loss. SIMS analysis was used in the case of oxygen diffusion and electron probe microanalysis (EPMA) in the case of cation diffusion. Both bulk and grain boundary diffusivities were determined.

The following expressions were obtained for cation and anion diffusion respectively.

D_{M}=2.5×10⁻⁵ exp[−1.96 eV/kT] cm²/s (4)

D_{O}=0.73 exp[−3.56 eV/kT] cm²/S (5)

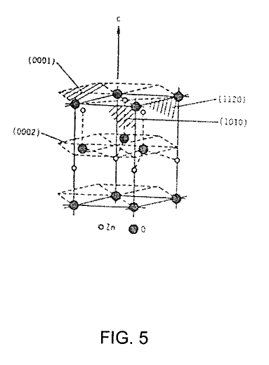

The larger cation than anion diffusivity in ZnO can be understood by reference to the crystalline structure. The lattice is composed of alternate layers of zinc and oxygen atoms (ions), as shown in FIG. 5, disposed in a wurtzite hexagonal closed-packed structure with a longitudinal axis. The zinc atoms only partially fill the voids among the oxygen spheres, due to the difference in sizes; this results in a relatively high volume of voids within the crystals and the correspondingly high Zn diffusivity. As might be expected, given the more highly disordered nature of the grain boundaries, grain boundary diffusion was found to be considerably greater than bulk diffusion.

The growth of ZnO on non-polar sapphire substrates led to films with (000-1) polarity (O-polar). However, the properties of materials having the wurtzite structure depend strongly on their polarity. It has been shown, for example, that in GaN, which also has the wurtzite structure, the film polarity affects the p-type doping efficiency as well as the performance of optical, electronic and electromechanical devices. In accordance with the invention, the growth of ZnO films in the (000-1) and (0001) polarities can be achieved by growing the films on the O- or Zn faces of the ZnO substrates. The polarity can be monitored by studying the film surface reconstruction during growth and upon cooling after the completion of growth. From the growth of heteroepitaxial, ZnO films it is known that O-polar films undergo 3×3 surface reconstruction, which is similar to the surface reconstruction of N-polar GaN at low temperatures. Therefore, in analogy to GaN, it is understood in accordance with the invention that a 2×2 surface reconstruction is produced for the Zn-polarity of ZnO films.

The electrical properties of the p- and n-type ZnO films can be examined, e.g., in two temperature regimes. The first is at temperatures in the vicinity of room temperature at which the films would normally be operated as components of, for example, rectifiers or light emitting diodes. The second is at higher temperatures, typically above ˜300-500° C., at which the films begin to interact with and exhibit sensitivity to the atmosphere. The latter regime is particularly important vis-a-vis establishing the optimum conditions to apply the TCD doping method of the invention.

A number of experimental tools including impedance spectroscopy, thermoelectric power, and diffusion, can be utilized to track the dependence of electronic carriers and defects in ZnO as functions of temperature, oxygen partial pressure, composition and impurity content. The results of these measurements then can be examined in relation to appropriate defect chemical models with the objective of identifying the key defects controlling the electrical and kinetic properties and extracting key thermodynamic and kinetic parameters.

To investigate the role of annealing conditions and high temperature stability of the materials, particularly the p-type ZnO, electrical characterization techniques can be carried out under controlled atmosphere and temperature conditions. The electrical conductivity of p-type films, grown on insulating substrates with Pt interdigitated electrodes without post-growth annealing, is understood to be low given donor-acceptor compensation as discussed above.

Systematic in-situ annealing experiments enable the establishment of conditions under which the transient donor species are driven off from the film while retaining the acceptor in solution. By monitoring the corresponding transient in conductivity, the so-called chemical diffusivity can be derived, which controls the kinetics of the process. Oxygen partial pressure is controlled using either gas mixtures (Ar/O₂ for high pO₂'s, CO/CO₂ buffer gas mixture for low pO₂'s) or an electrochemical oxygen pump.

The oxygen pump is preferably an yttria-doped zirconia tube, electroded with Pt electrodes both inside and out. Argon is passed through the tube as a voltage is applied to the electrodes, resulting in the flow of residual oxygen out of the argon gas. Precise control of the current flowing through the tube allows control of the oxygen partial pressure of the argon at the outlet of the pump. In both control methods, zirconia lambda sensors can be used to monitor pO₂ levels. A triple zone furnace provides accurate control of temperature gradients in the furnace, useful in thermoelectric power measurements. The system is capable of simultaneous automated collection of AC impedance, DC conductivity, and thermoelectric power data.

The overall electrical response of a polycrystalline solid is composed of a superposition of grain, grain boundary and electrode effects. For purposes of establishing the defect structure of a material, and in this case, establishing the effective acceptor density, it is imperative to isolate the bulk contributions from interfacial effects. Ideally, the spectral contributions of bulk, grain boundary and electrode are distinguished because of their distinctly different RC time constants. When this is not the case, one can utilize a number of approaches including change of grain size, specimen dimensions, and/or electrode material. Alternatively, one varies temperature, oxygen partial pressure and/or bias taking into account the different dependencies of the various contributions on these parameters. A number of fitting routines are useful in deconvoluting the individual contributions to the impedance spectra. Appropriate instrumentation can be provided as, e.g., Solartron 1250 and 1260 frequency response analyzers coupled with 1286 electrochemical interfaces, HP 4192A impedance analyzers, and a Mestek high impedance interface, and software appropriate for impedance studies as, e.g., Scribner Associates' ZPlot and ZView.

For samples with high levels of conductivity, 4-probe DC measurements are required to resolve the bulk from the electrode contributions. Precise current levels are supplied using an EDC 520A/521A/522A DC calibrator and voltage is measured using an HP3478A multimeter or HP34970A data acquisition system. This instrumentation can also be used to characterize the p-n junction characteristics including the ideality factor in the forward direction and the leakage currents and breakdown voltages under reverse bias. Transient conductivity measurements, i.e., the conductivity response after an abrupt change in pO₂ at a given temperature, yield chemical diffusivity data. The chemical diffusion coefficient is limited by the slower moving species, which provides additional insight into the defect structure and transport mechanisms.

The thermoelectric power (TEP) represents the open circuit voltage induced across a specimen due to an imposed thermal gradient. This method enables one to identify the charge of an electronic carrier, i.e. n or p type, as well as carrier concentration. Thus, when coupled with conductivity measurements, it enables the deconvolution of carrier density and carrier mobility. Since the hole mobility in ZnO is not well established and depends, in part, on the overall defect density, it can be preferred that it be evaluated for the samples produced in accordance with the invention. When both electrons and holes contribute, the interpretation of TEP is more complex.

Although the present invention has been shown and described with respect to several preferred embodiments thereof, various changes, omissions and additions to the form and detail thereof, may be made therein, without departing from the spirit and scope of the invention.

What is claimed is:

1. A method of p-type doping in ZnO comprising:
forming an acceptor-doped material having ZnO under reducing conditions, thereby insuring a high donor density; and
annealing the specimens of said acceptor-doped material at intermediate temperatures under oxidizing conditions so as to remove intrinsic donors and activate impurity acceptors.

2. The method of claim 1, wherein said reducing conditions comprise a hydrogen containing atmosphere.

3. The method of claim 1, wherein said reducing conditions comprise a non- hydrogen containing atmosphere.

4. The method of claim 1, wherein said acceptor-doped material comprises a substrate, a n-type ZnO layer deposited on said substrate, and a p-type layer deposited on said n-type ZnO layer.

5. The method of claim 1, wherein said intermediate temperatures comprise a temperature range between 200° C. and 700° C.

6. A method of forming p-n junctions using p-type ZnO comprising:
forming an acceptor-doped material having ZnO under reducing conditions, thereby insuring a high donor density; and
annealing the specimens of said acceptor-doped material at intermediate temperatures under oxidizing conditions so as to remove intrinsic donors and activate impurity acceptors.

7. The method of claim 6, wherein said reducing conditions comprise a hydrogen containing atmosphere.

8. The method of claim 6, wherein said reducing conditions comprise a non- hydrogen containing atmosphere.

9. The method of claim 6, wherein said acceptor-doped material comprises a substrate, a n-type ZnO layer deposited on said substrate, and a p-type layer deposited on said n-type ZnO layer.

10. The method of claim 6, wherein said intermediate temperatures comprises a temperature range between 200° C. and 700° C.

11. A wide band gap semiconductor device comprising an acceptor-doped material having ZnO that is formed under reducing conditions, thereby insuring a high donor density; wherein the specimens of said acceptor-doped material are annealed at intermediate temperatures under oxidizing conditions so as to remove intrinsic donors and activate impurity acceptors.

12. The wide band gap semiconductor device of claim 11, wherein said reducing conditions comprise a hydrogen containing atmosphere.

13. The wide band gap semiconductor device of claim 11, wherein said reducing conditions comprise a non- hydrogen containing atmosphere.

14. The wide band gap semiconductor device of claim 11, wherein said acceptor-doped material comprises a substrate, a n-type ZnO layer deposited on said substrate, and a p-type layer deposited on said n-type ZnO layer.

15. The wide band gap semiconductor device of claim 11, wherein said intermediate temperatures comprise a temperature range between 200° C. and 700° C.

16. A p-n junction comprising an acceptor-doped material having ZnO that is formed under reducing conditions, thereby insuring a high donor density; wherein the specimens of said acceptor-doped material are annealed at intermediate temperatures under oxidizing conditions so as to remove intrinsic donors and activate impurity acceptors.

17. The p-n junction of claim 16, wherein said reducing conditions comprise a hydrogen containing atmosphere.

18. The p-n junction of claim 16, wherein said reducing conditions comprise a non-hydrogen containing atmosphere.

19. The p-n junction of claim 16, wherein said acceptor-doped material comprises a substrate, a n-type ZnO layer deposited on said substrate, and a p-type layer deposited on said n-type ZnO layer.

20. The p-n junction of claim 16, wherein said intermediate temperatures comprises a temperature range between 200° C. and 700° C.
